(19) United States
(12) Patent Application Publication
(10) Pub. No.: US 2025/0226336 A1
(43) Pub. Date: Jul. 10, 2025

(54) SEMICONDUCTOR PACKAGE STRUCTURE

(71) Applicant: MediaTek Singapore Pte. Ltd., Singapore (SG)

(72) Inventors: Zhigang DUAN, Singapore (SG); Chang LIANG, Singapore (SG); Jubao ZHANG, Singapore (SG)

(21) Appl. No.: 18/405,172

(22) Filed: Jan. 5, 2024

(51) Int. Cl. H01L 23/64; H01L 23/00; H01L 23/498; H01L 23/522; H01L 25/065; H01L 25/16

(52) U.S. Cl. CPC H01L 23/642; H01L 23/49822; H01L 23/5222; H01L 24/16; H01L 24/48; H01L 24/73; H01L 25/0655; H01L 25/0657; H01L 25/16; H01L 2224/16225; H01L 2224/48137; H01L 2224/48145; H01L 2224/48225; H01L 2224/73257; H01L 2225/06506; H01L 2924/19041

(57) ABSTRACT

A semiconductor package structure includes a first substrate, a capacitor structure, a plurality of first conductive connectors, and a plurality of second conductive connectors. The capacitor structure includes a semiconductor substrate, a first capacitor, and a second capacitor. The semiconductor substrate has a first surface and a second surface opposite the first surface. The first capacitor is disposed on the first surface of the semiconductor substrate. The second capacitor is disposed on the second surface of the semiconductor substrate. The first conductive connectors are disposed over the capacitor structure and electrically coupled to the first capacitor. The second conductive connectors are disposed below the capacitor structure and electrically coupled to the second capacitor.

### BACKGROUND OF THE INVENTION

### Field of the Invention

The present invention relates to semiconductor technology, and, in particular, to a semiconductor package structure including a capacitor structure.

### Description of the Related Art

A semiconductor package structure can not only provide a semiconductor die with protection from environmental contaminants, but it can also provide an electrical connection between the semiconductor die packaged therein and a substrate, such as a printed circuit board (PCB).

As high-performance integrated circuits demand larger currents at higher frequencies with lower power-supply voltages, power system design has become increasingly challenging. Decoupling capacitors may be adopted to act as temporary charge reservoirs to prevent momentary fluctuations in supply voltage. The decoupling capacitors are more and more important to reduce power noise.

However, although existing semiconductor package structures generally meet requirements, they have not been satisfactory in every respect. For example, while the size of electronic components such as transistors and resistors is getting smaller, capacitor structures still need to take up more space than other electronic components owing to their physical properties. This is unfavorable for the miniaturization of semiconductor package structures. Therefore, further improvements to semiconductor package structures are required.

### BRIEF SUMMARY OF THE INVENTION

Semiconductor package structures are provided. An exemplary embodiment of a semiconductor package structure includes a first substrate, a capacitor structure, a plurality of first conductive connectors, and a plurality of second conductive connectors. The capacitor structure includes a semiconductor substrate, a first capacitor, and a second capacitor. The semiconductor substrate has a first surface and a second surface opposite the first surface. The first capacitor is disposed on the first surface of the semiconductor substrate. The second capacitor is disposed on the second surface of the semiconductor substrate. The first conductive connectors are disposed over the capacitor structure and electrically coupled to the first capacitor. The second conductive connectors are disposed below the capacitor structure and electrically coupled to the second capacitor.

Another embodiment of a semiconductor package structure includes a substrate, a redistribution layer, a redistribution layer, a capacitor structure, and a first semiconductor die. The redistribution layer is disposed over the substrate. The capacitor structure is disposed over the redistribution layer and electrically coupled to the redistribution layer. The capacitor structure includes a semiconductor substrate, a first capacitor, and a second capacitor. The first capacitor is disposed over the semiconductor substrate. The second capacitor is disposed below the semiconductor substrate and vertically overlaps the first capacitor. The first semiconductor die is disposed over the redistribution layer and electrically coupled to the redistribution layer.

Yet another embodiment of a semiconductor package structure includes a substrate, a semiconductor die, and a capacitor structure. The semiconductor die is disposed over the substrate. The capacitor structure is disposed between the substrate and the first semiconductor die. The capacitor structure includes a semiconductor substrate, a first capacitor, and a second capacitor. The first capacitor is disposed over the semiconductor substrate and electrically coupled to the first semiconductor die. The second capacitor is disposed below the semiconductor substrate and electrically coupled to the substrate. The first capacitor vertically overlaps the second capacitor.

### BRIEF DESCRIPTION OF THE DRAWINGS

The present invention can be more fully understood by reading the subsequent detailed description and examples with references made to the accompanying drawings, wherein:

FIGS. 1A to 1D are cross-sectional views of various stages of manufacturing an exemplary capacitor structure in accordance with some embodiments of the present disclosure;

FIG. 2 is a cross-sectional view of an exemplary semiconductor package structure in accordance with some embodiments of the present disclosure;

FIG. 3 is a cross-sectional view of an exemplary semiconductor package structure in accordance with some embodiments of the present disclosure;

FIG. 4 is a cross-sectional view of an exemplary semiconductor package structure in accordance with some embodiments of the present disclosure; and

FIG. 5 is a cross-sectional view of an exemplary semiconductor package structure in accordance with some embodiments of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the disclosure.

Additional elements may be added on the basis of the embodiments described below. For example, the description of “a first element on/over a second element” may include embodiments in which the first element is in direct contact with the second element, and may also include embodiments in which additional elements are disposed between the first element and the second element such that the first element and the second element are not in direct contact.

The spatially relative descriptors of the first element and the second element may change as the structure is operated or used in different orientations. In addition, the present disclosure may repeat reference numerals and/or letters in the various embodiments. This repetition is for simplicity and clarity and does not in itself dictate a relationship between the various embodiments discussed.

A semiconductor package structure including a capacitor structure is described in accordance with some embodiments of the present disclosure. The capacitor structure includes stacked capacitors formed on opposite sides of a semiconductor substrate. As a result, the capacitance density can be increased.

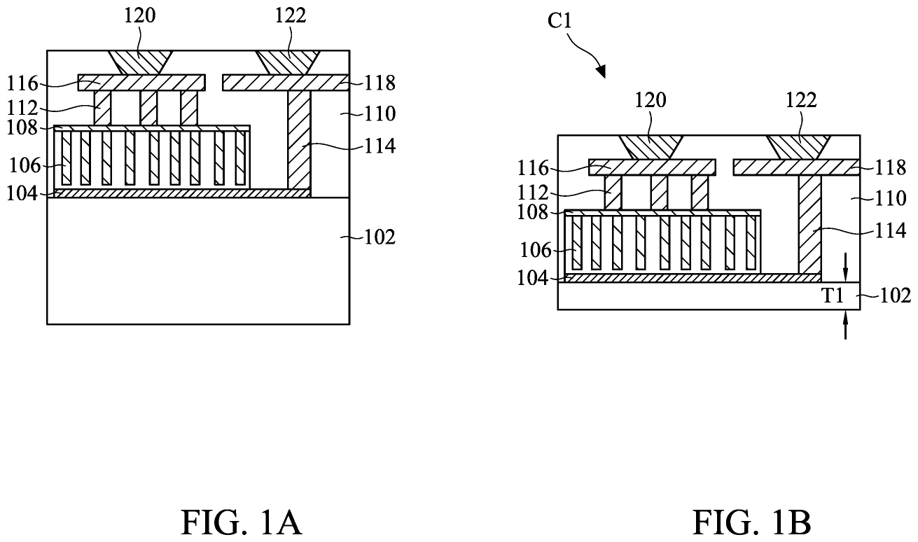

FIGS. 1A to 1D are cross-sectional views of various stages of manufacturing a capacitor structure 100 in accordance with some embodiments of the present disclosure. Additional features can be added to the capacitor structure 100. Some of the features described below can be replaced or eliminated for different embodiments. To simplify the diagram, only a portion of the capacitor structure 100 is illustrated.

As illustrated in FIG. 1A, a semiconductor substrate 102 is provided, in accordance with some embodiments. The semiconductor substrate 102 may be formed of any suitable semiconductor material, such as silicon, germanium, silicon carbon, silicon germanium, gallium arsenide, indium arsenide, indium phosphide, the like, or a combination thereof. The semiconductor substrate 102 may include a bulk semiconductor or a composite substrate formed of different materials. The semiconductor substrate 102 may include a semiconductor-on-insulator (SOI) substrate formed by a semiconductor material on an insulating layer, such as a silicon-on-insulator substrate.

The semiconductor substrate 102 may be doped (e.g., using p-type or n-type dopants) or undoped. Any desired semiconductor elements (including active elements and/or passive elements) may be formed in and on the semiconductor substrate 102. However, in order to simplify the figures, only the flat semiconductor substrate 102 is illustrated.

Afterwards, a first metal layer 104, a capacitor 106, and a second metal layer 108 are sequentially formed over the semiconductor substrate 102, in accordance with some embodiments. The first metal layer 104 and the second metal layer 108 may each independently be formed of metal, including tungsten, titanium, tantalum, ruthenium, cobalt, copper, aluminum, platinum, tin, silver, gold, the like, an alloy thereof, or a combination thereof. The capacitor 106 may include a silicon capacitor.

The length of the first metal layer 104 may be greater than the length of the second metal layer 108. The sidewalls of the second metal layer 108 may align the sidewalls of the capacitor 106. The first metal layer 104 may extend beyond the sidewall of the capacitor 106.

Then, a dielectric layer 110 is formed over the semiconductor substrate 102 and surrounds the first metal layer 104, the capacitor 106, and the second metal layer 108, in accordance with some embodiments. The dielectric layer 110 may be formed of dielectric materials, including silicon oxide, silicon nitride, silicon oxynitride, the like, or a combination thereof, and may be formed by a deposition process.

Afterwards, a plurality of conductive vias 112 and 114 are formed in the dielectric layer 110, in accordance with some embodiments. The conductive vias 112 and 114 may each independently be formed of metal, including tungsten, titanium, tantalum, ruthenium, cobalt, copper, aluminum, platinum, tin, silver, gold, the like, an alloy thereof, or a combination thereof, and may be formed by a deposition process.

Then, a conductive layer 116 may be formed over the conductive vias 112, and a conductive layer 118 may be formed over the conductive vias 114. The conductive layer 116 may be electrically coupled to the second metal layer 108 through the conductive vias 112, and the conductive layer 118 may be electrically coupled to the first metal layer 104 through the conductive vias 114. The conductive layers 116 and 118 may each independently be formed of metal, including tungsten, titanium, tantalum, ruthenium, cobalt, copper, aluminum, platinum, tin, silver, gold, the like, an alloy thereof, or a combination thereof, and may be formed by a deposition process.

Then, a conductive pad 120 is formed over the conductive layer 116, and a conductive pad 122 is formed over the conductive layer 118, in accordance with some embodiments. The conductive pad 120 may be electrically coupled to the conductive layer 116, and the conductive pad 122 may be electrically coupled to the conductive layer 118. The conductive pads 120 and 122 may each independently be formed of metal, including tungsten, titanium, tantalum, ruthenium, cobalt, copper, aluminum, platinum, tin, silver, gold, the like, an alloy thereof, or a combination thereof, and may be formed by a deposition process.

Afterwards, as illustrated in FIG. 1B, a grinding process is performed to thin the semiconductor substrate 102, and a structure C1 is formed, in accordance with some embodiments. After the grinding process, the semiconductor substrate 102 may have a thickness T1 in a range of about 20 μm to about 70 μm.

Then, as illustrated in FIG. 1C, a first metal layer 134, a capacitor 136, and a second metal layer 138 may be sequentially formed over a semiconductor substrate 132. A dielectric layer 140 may be formed over the semiconductor substrate 132 and may surround the first metal layer 134, the capacitor 136, and the second metal layer 138. A plurality of conductive vias 142, 144, conductive layers 146, 148, and conductive pads 150, 152 may be formed in the dielectric layer 140. These components may be similar to the semiconductor substrate 102, the first metal layer 104, the capacitor 106, the second metal layer 108, the dielectric layer 110, the conductive vias 112, 114, the conductive layers 116 and 118, and the conductive pads 120 and 122, respectively, and will not be described in detail.

The conductive pad 150 may be electrically coupled to the conductive layer 146, the conductive vias 142, and the second metal layer 138. The conductive pad 152 may be electrically coupled to the conductive layer 148, the conductive vias 144, and the first metal layer 134.

Afterwards, a grinding process may be performed to thin the semiconductor substrate 132, and a structure C2 is formed. After the grinding process, the semiconductor substrate 132 may have a thickness T2 in a range of about 20 μm to about 70 μm. The thickness T2 of the semiconductor substrate 132 may be substantially equal to the thickness T1 of the semiconductor substrate 102.

Then, as illustrated in FIG. 1D, the structure C2 is stacked over the structure C1, in accordance with some embodiments. The structure C1 and the structure C2 may be stacked by bonding the semiconductor substrates 102 and 132 using fusion bonding or any suitable bonding method. The backside of the semiconductor substrate 102 may be in contact with the backside of the semiconductor substrate 132.

The capacitor 106 may at least partially vertically overlap the capacitor 136. In particular, the capacitor 106 may overlap the capacitor 136 in a direction substantially vertical to the top surface of the semiconductor substrate 102. As a result, the capacitance can be increased without taking up larger area.

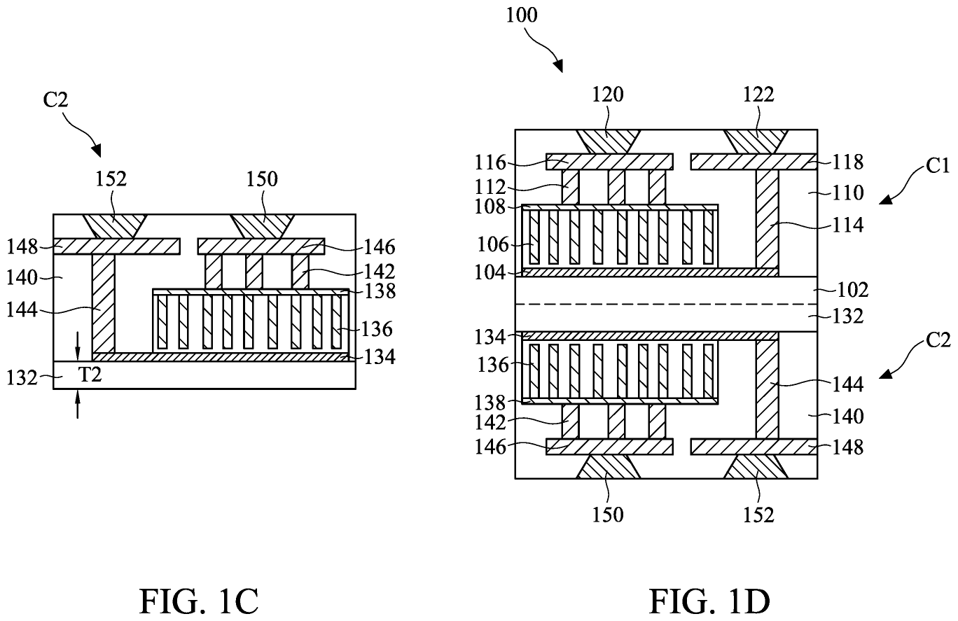

Afterwards, a plurality of conductive connectors (such as conductive connectors 208 as illustrated in FIG. 2) may be formed on the conductive pads 120 and 122 and the conductive pads 150 and 152. The conductive connectors may include microbumps, wire bonds, copper pillar bumps, the like, or a combination thereof. Then, a sawing process may be performed to form the capacitor structure 100. The sidewalls of the dielectric layers 110, 140 and the semiconductor substrates 102, 132 may be substantially coplanar.

FIG. 2 is a cross-sectional view of a semiconductor package structure 200 in accordance with some embodiments of the present disclosure. Additional features can be added to the semiconductor structure 200. Some of the features described below can be replaced or eliminated for different embodiments. To simplify the diagram, only a portion of the semiconductor structure 200 is illustrated.

As shown in FIG. 2, the semiconductor package structure 200 includes a substrate 202, in accordance with some embodiments. The substrate 202 may be a printed circuit board (PCB). The substrate 202 may include one or more layers of electrically-conductive traces. It should be noted that the configuration of the substrate 202 shown in the figures is exemplary only and is not intended to limit the present disclosure. Any desired semiconductor element may be formed in and on the substrate 202. However, in order to simplify the diagram, only the flat substrate 202 is illustrated.

The semiconductor package structure 200 includes a substrate 206 disposed over the substrate 202 and electrically coupled to the substrate 202 through a plurality of conductive terminals 204. The conductive terminals 204 may include ball grid array (BGA) balls, land grid array (LGA) pads, pin grid array (PGA) pins, the like, or a combination thereof.

The substrate 206 may have a wiring structure therein. In some embodiments, the wiring structure includes conductive pads, conductive vias, conductive lines, conductive pillars, the like, or a combination thereof. The wiring structure may be formed of metal, such as tungsten, titanium, tantalum, ruthenium, cobalt, copper, aluminum, platinum, tin, silver, gold, the like, an alloy thereof, or a combination thereof.

The wiring structure may be disposed in dielectric layers. The dielectric layers may be formed of polymer, including polyimide (PI), polybenzoxazole (PBO), benzocyclobutene (BCB), epoxy, the like, or a combination thereof. Alternatively, the dielectric layers may be formed of silicon oxide, silicon nitride, silicon oxynitride, the like, or a combination thereof. In some embodiments, the substrate 206 may be a redistribution layer.

In some embodiments, the capacitor structure 100 is disposed over the substrate 206. A plurality of conductive connectors 208 may be disposed on opposite surfaces of the capacitor structure 100 and may be electrically coupled to conductive pads (such as the conductive pads 120, 122, 150, 152 as shown in FIG. 1D) of the capacitor structure 100. The conductive connectors 208 may include microbumps, wire bonds, copper pillar bumps, the like, or a combination thereof. For example, the conductive connectors 208 may be microbumps. The conductive connectors 208 may be formed of metal.

The semiconductor package structure 200 includes a semiconductor die 212 disposed over the capacitor structure 100, in accordance with some embodiments. In some embodiments, the semiconductor die 212 includes a system-on-chip (SoC) die, a logic device, a memory device, a radio frequency (RF) device, the like, or a combination thereof. For example, the semiconductor die 212 may include a micro control unit (MCU) die, a microprocessor unit (MPU) die, a power management integrated circuit (PMIC) die, a radio frequency front end (RFFE) die, an accelerated processing unit (APU) die, a central processing unit (CPU) die, a graphics processing unit (GPU) die, an input-output (IO) die, a dynamic random access memory (DRAM) controller, a static random-access memory (SRAM), a high bandwidth memory (HBM), an application processor (AP) die, an application specific integrated circuit (ASIC) die, the like, or a combination thereof.

It should be noted that the number of semiconductor die is shown for illustrative purposes only, and more than one semiconductor die may be disposed over the substrate 206. In addition, one or more passive components (not illustrated) may be disposed over the substrate 206, such as resistors, capacitors, inductors, the like, or a combination thereof.

The semiconductor die 212 may be electrically coupled to one of the capacitors (such as the capacitor 106 as shown in FIG. 1D) of the capacitor structure 100 through the conductive connectors 208, and the substrate 206 may be electrically coupled to another one of the capacitors (such as the capacitor 136 as shown in FIG. 1D) of the capacitor structure 100 through the conductive connectors 208.

The semiconductor package structure 200 includes a plurality of conductive pillars 210 electrically coupling the substrate 206 and the semiconductor die 212, in accordance with some embodiments. The conductive pillars 210 may be formed of metal. The conductive pillars 210 may be adjacent to the capacitor structure 100 and may have a greater height than the capacitor structure 100. In particular, the height of the conductive pillar 210 may be equal to the total height of one of the conductive connectors 208 on the top surface of the capacitor structure 100, the capacitor structure 100, and one of the conductive connectors 208 on the bottom surface of the capacitor structure 100.

In the above embodiment, the capacitor structure 100 including stacked capacitors can be electrically coupled to the substrate 206 and the semiconductor die 212 on opposite surfaces, so that the capacitance density can be enhanced.

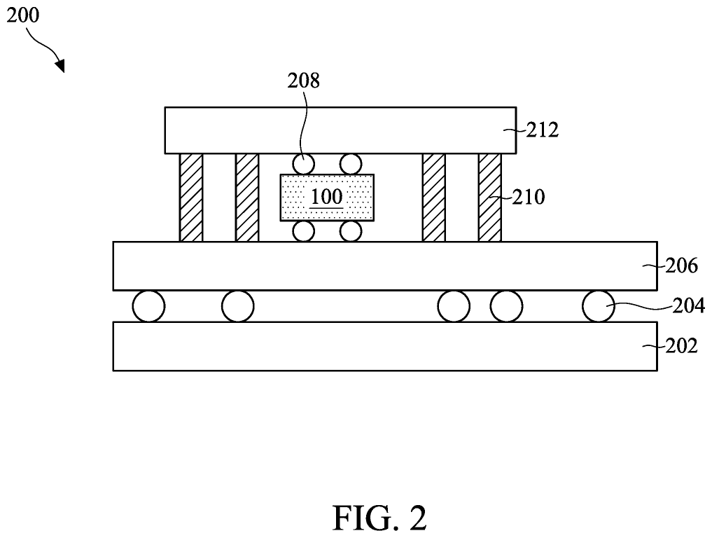

FIG. 3 is a cross-sectional view of a semiconductor package structure 300 in accordance with some embodiments of the present disclosure. It should be noted that the semiconductor package structure 300 may include the same or similar components as that of the semiconductor package structure 200, which is illustrated in FIG. 2, and for the sake of simplicity, those components will not be discussed in detail again. In the following embodiments, a capacitor structure is disposed over a semiconductor die.

As shown in FIG. 3, the semiconductor package structure 300 includes a substrate 302, in accordance with some embodiments. The substrate 302 may be similar to the substrate 202 as illustrated in FIG. 2, and will not be repeated.

The semiconductor package structure 300 includes a substrate 306 disposed over the substrate 302 and electrically coupled to the substrate 302 through a plurality of conductive terminals 304. The conductive terminals 304 may include ball grid array (BGA) balls, land grid array (LGA) pads, pin grid array (PGA) pins, the like, or a combination thereof.

The substrate 306 may have a wiring structure 308. In some embodiments, the wiring structure 308 includes conductive pads, conductive vias, conductive lines, conductive pillars, the like, or a combination thereof. The wiring structure 308 may be formed of metal, such as tungsten, titanium, tantalum, ruthenium, cobalt, copper, aluminum, platinum, tin, silver, gold, the like, an alloy thereof, or a combination thereof.

The wiring structure 308 may be disposed in dielectric layers. The dielectric layers may be formed of polymer, including polyimide (PI), polybenzoxazole (PBO), benzocyclobutene (BCB), epoxy, the like, or a combination thereof. Alternatively, the dielectric layers may be formed of silicon oxide, silicon nitride, silicon oxynitride, the like, or a combination thereof. In some embodiments, the substrate 306 may be a redistribution layer.

The semiconductor package structure 300 includes a first semiconductor die 310 and a second semiconductor die 316 stacked over the substrate 306, in accordance with some embodiments. The first semiconductor die 310 and the second semiconductor die 316 may each include the devices discussed above with respect to the semiconductor die 212 as illustrated in FIG. 2, and will not be repeated.

The first semiconductor die 310 and the second semiconductor die 316 may include the same or different devices. For example, the first semiconductor die 310 may include an ASIC, and the second semiconductor die 316 may include a memory device. It should be noted that the number of semiconductor dies is shown for illustrative purposes only, and more than two semiconductor dies may be disposed over the substrate 306. For example, more than one semiconductor die may be disposed over the first semiconductor die 310. In addition, one or more passive components (not illustrated) may be disposed over the substrate 306, such as resistors, capacitors, inductors, the like, or a combination thereof.

The first semiconductor die 310 and the second semiconductor die 316 may be electrically coupled to the substrate 306 through a plurality of conductive connectors 312, and may be electrically coupled to each other through a plurality of conductive connectors 314. The conductive connectors 312 and 314 may include wire bonds, and may be formed of metal.

In some embodiments, the capacitor structure 100 is disposed over the first semiconductor die 310 and adjacent to the second semiconductor die 316. A plurality of conductive connectors 318 and 320 may be disposed on opposite surfaces of the capacitor structure 100 and may be electrically coupled to capacitors of the capacitor structure 100 (such as the capacitors 106 and 136 as shown in FIG. 1D).

The conductive connectors 318 and 320 may each independently include microbumps, wire bonds, copper pillar bumps, the like, or a combination thereof, and may be formed of metal. For example, the conductive connectors 318 may be microbumps, and the conductive connectors 320 may be wire bonds. The conductive connectors 318 and 320 may be electrically coupled to the first semiconductor die 310.

In the above embodiment, the capacitor structure 100 including stacked capacitors can be electrically coupled to the first semiconductor die 310 on opposite surfaces, so that the capacitance density can be enhanced.

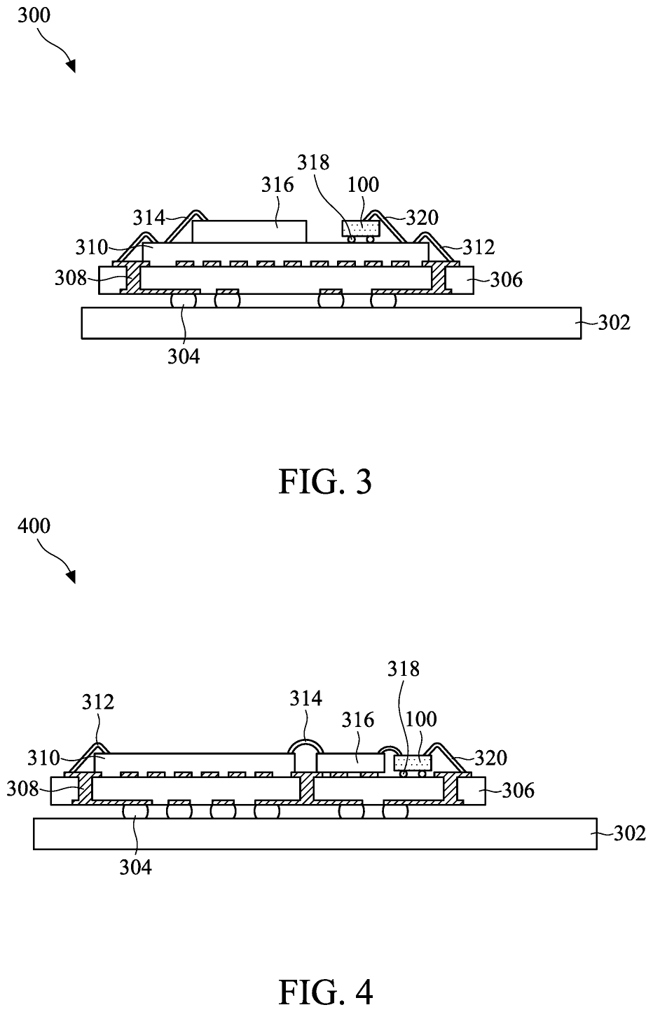

FIG. 4 is a cross-sectional view of a semiconductor package structure 400 in accordance with some embodiments of the present disclosure. It should be noted that the semiconductor package structure 400 may include the same or similar components as that of the semiconductor package structure 300, which is illustrated in FIG. 3, and for the sake of simplicity, those components will not be discussed in detail again. In the following embodiments, a capacitor structure and a semiconductor die are disposed side-by-side.

As shown in FIG. 4, the first semiconductor die 310 and the second semiconductor die 316 are disposed side-by-side over the substrate 306. The first semiconductor die 310 and the second semiconductor die 316 may be electrically coupled to the substrate 306 through the conductive connectors 312, and may be electrically coupled to each other through the conductive connectors 314. The conductive connectors 312 and 314 may include wire bonds.

The capacitor structure 100 may be disposed over the substrate 306 and adjacent to the second semiconductor die 316. The conductive connectors 318 and 320 may be disposed on opposite surfaces of the capacitor structure 100 and may be electrically coupled to capacitors of the capacitor structure 100 (such as the capacitors 106 and 136 as shown in FIG. 1D).

The conductive connectors 318 and 320 may each independently include microbumps, wire bonds, copper pillar bumps, the like, or a combination thereof, and may be formed of metal. For example, the conductive connectors 318 may be microbumps, and the conductive connectors 320 may be wire bonds. The conductive connectors 318 may be electrically coupled to the substrate 306, and the conductive connectors 320 may be electrically coupled to the substrate 306 and the second semiconductor die 316.

In the above embodiment, the capacitor structure 100 including stacked capacitors can be electrically coupled to the substrate 306 and the second semiconductor die 316 on opposite surfaces, so that the capacitance density can be enhanced.

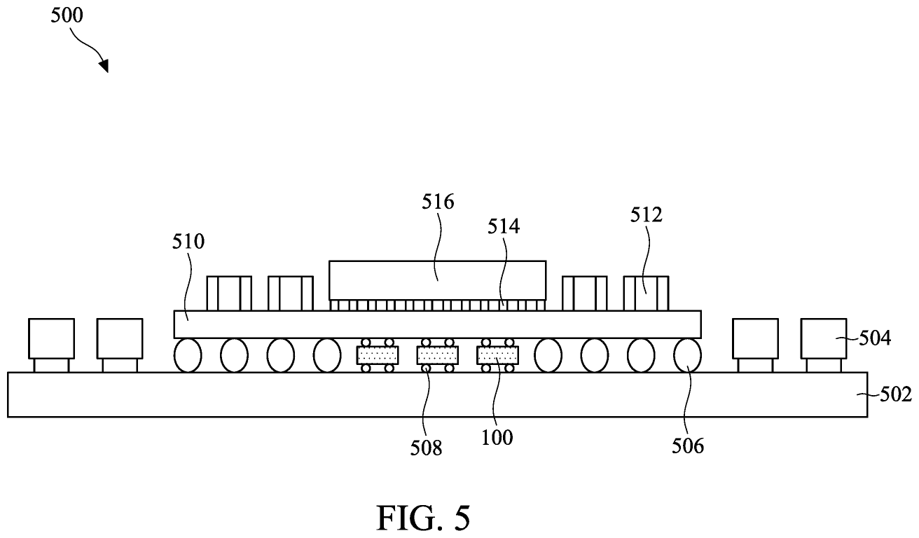

FIG. 5 is a cross-sectional view of a semiconductor package structure 500 in accordance with some embodiments of the present disclosure. It should be noted that the semiconductor package structure 500 may include the same or similar components as that of the semiconductor package structure 200, which is illustrated in FIG. 2, and for the sake of simplicity, those components will not be discussed in detail again. In the following embodiments, a capacitor structure is disposed between substrates.

As shown in FIG. 5, the semiconductor package structure 500 includes a substrate 510 disposed over a substrate 502 and electrically coupled to the substrate 502 through a plurality of conductive terminals 506, in accordance with some embodiments. The substrate 502, the conductive terminals 506, and the substrate 510 may be similar to the substrate 202, the conductive terminals 204, and the substrate 206 as illustrated in FIG. 2, and will not be repeated.

In some embodiments, the capacitor structure 100 is disposed between the substrate 502 and the substrate 510. A plurality of conductive connectors 508 may be disposed on opposite surfaces of the capacitor structure 100 and may be electrically coupled to capacitors of the capacitor structure 100 (such as the capacitors 106 and 136 as shown in FIG. 1D). The conductive connectors 508 may include microbumps, wire bonds, copper pillar bumps, the like, or a combination thereof. For example, the conductive connectors 508 may be microbumps, and may be electrically coupled to the substrate 502 and the substrate 510.

The semiconductor package structure 500 includes a semiconductor die 516 disposed over the substrate 510, in accordance with some embodiments. The semiconductor die 516 may include the devices discussed above with respect to the semiconductor die 212 as illustrated in FIG. 2, and will not be repeated. It should be noted that the number of semiconductor dies is shown for illustrative purposes only, and more than one semiconductor die may be disposed over the substrate 510.

The semiconductor die 516 may be electrically coupled to the substrate 510 through a plurality of conductive connectors 514. The conductive connectors 514 may include microbumps, copper pillar bumps, the like, or a combination thereof, and may be formed of metal.

The semiconductor package structure 500 includes one or more passive components 504 disposed over the substrate 502 and one or more passive components 512 disposed over the substrate 510, in accordance with some embodiments. The passive components 504 and 512 may each independently include resistors, capacitors, inductors, the like, or a combination thereof. In some embodiments, the passive components 504 include bulk capacitors, and the passive components 512 include multi-layer ceramic capacitors (MLCC).

In the above embodiment, the capacitor structure 100 including stacked capacitors can be electrically coupled to the substrate 502 and the substrate 510 on opposite surfaces, so that the capacitance density can be enhanced.

In summary, the semiconductor package structure according to the present disclosure includes a capacitor structure, which includes stacked capacitors formed on opposite sides of a semiconductor substrate. As a result, semiconductor components can be electrically coupled to the capacitors on opposite surfaces of the capacitor structure. Thus, the capacitance density can be increased.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor package structure, comprising:
a first substrate;
a capacitor structure disposed over the first substrate and comprising:
a semiconductor substrate having a first surface and a second surface opposite the first surface;
a first capacitor disposed on the first surface of the semiconductor substrate; and
a second capacitor disposed on the second surface of the semiconductor substrate; and
a plurality of first conductive connectors disposed over the capacitor structure and electrically coupled to the first capacitor; and
a plurality of second conductive connectors disposed below the capacitor structure and electrically coupled to the second capacitor.

2. The semiconductor package structure as claimed in claim 1, wherein the capacitor structure further comprises:
a first metal layer disposed between the semiconductor substrate and the first capacitor and electrically coupled to one of the first conductive connectors; and
a second metal layer disposed over a top surface of the first capacitor and electrically coupled to another one of the first conductive connectors.

3. The semiconductor package structure as claimed in claim 2, wherein the capacitor structure further comprises:
a dielectric layer disposed on the first surface of the semiconductor substrate and surrounding the first metal layer, the first capacitor, and the second metal layer.

4. The semiconductor package structure as claimed in claim 2, wherein a length of the first metal layer is greater than a length of the second metal layer.

5. The semiconductor package structure as claimed in claim 1, wherein the first capacitor vertically overlaps the second capacitor.

6. The semiconductor package structure as claimed in claim 1, wherein the first conductive connectors and the second conductive connectors each comprises microbumps, wire bonds, copper pillar bumps, or a combination thereof.

7. The semiconductor package structure as claimed in claim 1, further comprising:
a second substrate disposed over the capacitor structure and electrically coupled to the first substrate through a plurality of conductive terminals, wherein the capacitor structure is disposed between the plurality of conductive terminals; and
a semiconductor die disposed over the second substrate.

8. The semiconductor package structure as claimed in claim 7, wherein the first conductive connectors are electrically coupled to the second substrate and the second conductive connectors are electrically coupled to the first substrate.

9. A semiconductor package structure, comprising:
a substrate;
a redistribution layer disposed over the substrate;
a capacitor structure disposed over the redistribution layer and electrically coupled to the redistribution layer, wherein the capacitor structure comprises:
a semiconductor substrate;
a first capacitor disposed over the semiconductor substrate; and
a second capacitor disposed below the semiconductor substrate and vertically overlapping the first capacitor; and
a first semiconductor die disposed over the redistribution layer and electrically coupled to the redistribution layer.

10. The semiconductor package structure as claimed in claim 9, wherein the first semiconductor die is disposed over the capacitor structure and electrically coupled to the first capacitor, and the redistribution layer is electrically coupled to the second capacitor.

11. The semiconductor package structure as claimed in claim 10, further comprising:
a conductive pillar adjacent to the capacitor structure and electrically coupling the first semiconductor die to the redistribution layer.

12. The semiconductor package structure as claimed in claim 9, wherein the capacitor structure is disposed over the first semiconductor die and electrically coupled to the first semiconductor die through a first wire bond.

13. The semiconductor package structure as claimed in claim 12, further comprising a second semiconductor die disposed over the first semiconductor die and electrically coupled to the first semiconductor die through a second wire bond.

14. The semiconductor package structure as claimed in claim 12, wherein the first semiconductor die is electrically coupled to the redistribution layer through a second wire bond.

15. The semiconductor package structure as claimed in claim 9, wherein the capacitor structure is adjacent to the first semiconductor die, wherein the capacitor structure and the first semiconductor die are electrically coupled to the redistribution layer through first wire bonds.

16. The semiconductor package structure as claimed in claim 15, further comprising a second semiconductor die disposed over the redistribution layer and electrically coupled to the capacitor structure and the first semiconductor die through second wire bonds.

17. A semiconductor package structure, comprising:
a substrate;
a semiconductor die disposed over the substrate;
a capacitor structure disposed between the substrate and the first semiconductor die and comprising:
a semiconductor substrate;
a first capacitor disposed over the semiconductor substrate and electrically coupled to the first semiconductor die; and
a second capacitor disposed below the semiconductor substrate and electrically coupled to the substrate,
wherein the first capacitor vertically overlaps the second capacitor.

18. The semiconductor package structure as claimed in claim 17, further comprising:
a conductive pillar disposed over the substrate and electrically coupling the semiconductor die to the substrate; and
a plurality of conductive terminals disposed below the substrate.

19. The semiconductor package structure as claimed in claim 18, further comprising:
a first conductive connector electrically coupling the first capacitor to the first semiconductor die; and
a second conductive connector electrically coupling the second capacitor to the substrate.

20. The semiconductor package structure as claimed in claim 19, wherein a height of the conductive pillar is equal to a total height of the first conductive connector, the capacitor structure, and the second conductive connector.
